(19) United States
(12) Patent Application Publication
(10) Pub. No.: US 2024/0321729 A1
(43) Pub. Date: Sep. 26, 2024

(54) INTEGRATED REDISTRIBUTION LAYER INDUCTORS

(71) Applicant: QUALCOMM Incorporated, San Diego, CA (US)

(72) Inventors: Abhijeet PAUL, Escondido, CA (US); Ravi Pramod Kumar VEDULA, San Diego, CA (US); Yufei WU, San Diego, CA (US)

(21) Appl. No.: 18/186,781

(22) Filed: Mar. 20, 2023

(51) Int. Cl. H01L 23/522

(52) U.S. Cl. CPC H01L 23/5227; H01L 28/10

(57) ABSTRACT

Disclosed is an integrated circuit (IC) with an inductor formed from redistribution layers (RDLs). An airgap is provided in an interlayer dielectric (ILD) under the bottom most RDL that makes up the inductor. In this way, an inductor with high Q value is achieved. Also, inductor isolation is improved. Thus, circuits may be placed under the inductor resulting is a smaller die.

### FIELD OF DISCLOSURE

This disclosure relates generally to integrated circuits, and more specifically, but not exclusively, to integrated circuits with integrated redistribution layer (RDL) inductors, and fabrication techniques thereof.

### BACKGROUND

Integrated circuit technology has achieved great strides in advancing computing power through miniaturization of active components. The devices, such as semiconductor devices, can be found in many electronic devices, including processors, servers, radio frequency (RF) integrated circuits, etc.

In RF front end (RFFE) applications (e.g., degeneration, transformers, couplers, etc.), use of inductors is very high. While inductors are useful, they also come with issues. One issue is that on-chip inductors suffer from poor Q values (bulk shows Q values about 6-10) and RF silicon-on-insulator (RFSOI) show about 10-12 @ 5 GHz. The poor Q is mainly due to thinner copper (Cu) and large coupling to the substrate. This leads to poor performance in the circuit. Another issue is that area under the inductors cannot be filled with circuits due to isolation and RF coupling issues. This leads to larger die sizes and lower dies per wafer (DPW).

Accordingly, there is a need for systems, apparatus, and methods that overcome the deficiencies of conventional integrated circuits with inductors including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary integrated circuit is disclosed. The integrated circuit may comprise a plurality of metals and a plurality of insulators alternatively stacked. A first metal may be a top most metal among the plurality of metals. The integrated circuit may also comprise one or more redistribution layers (RDL) above the plurality of metals. A first RDL may be a bottom most RDL among the one or more RDLs. The integrated circuit may further comprise one or more interlayer dielectrics (ILD) corresponding to each of the one or more RDLs. Each ILD may encapsulate a corresponding RDL. For example, a first ILD may encapsulate the first RDL. The integrated circuit may yet comprise a first airgap formed in the first ILD under the first RDL. The one or more RDLs may be configured as an inductor.

A method of fabricating an exemplary integrated circuit is disclosed. The method may comprise forming a plurality of metals and a plurality of insulators alternatively stacked. A first metal may be a top most metal among the plurality of metals. The method may also comprise forming one or more redistribution layers (RDL) above the plurality of metals. A first RDL may be a bottom most RDL among the one or more RDLs. The method may further comprise forming one or more interlayer dielectrics (ILD) corresponding to each of the one or more RDLs. Each ILD may encapsulate a corresponding RDL. For example, a first ILD may encapsulate the first RDL. The method may yet comprise forming a first airgap formed in the first ILD under the first RDL. The one or more RDLs may be configured as an inductor.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates an example of a conventional integrated circuit.

FIG. 2 illustrates an example of an integrated circuit in accordance with or more aspects of the disclosure.

FIG. 3 illustrates an example of an integrated circuit in accordance with or more aspects of the disclosure.

FIGS. 4 and 5 illustrate flow charts of example methods of manufacturing an integrated circuit in accordance with at one or more aspects of the disclosure.

FIG. 6 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises.” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof.

As indicated above, inductors are useful, but they can come with issues. One issue is that on-chip inductors suffer from poor Q values, primarily due to thinner copper (Cu) and large coupling to the substrate. Thus, conventional inductors can lead to poor performance in the circuit. This can be compensated for in some degree with options such as “off-chip” inductors. Unfortunately, this can be an expensive solution.

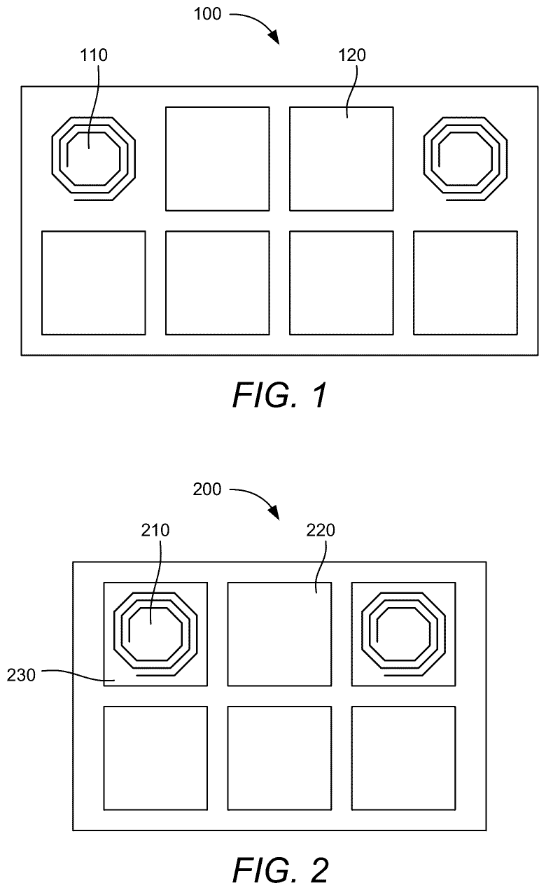

Another issue is that area under the conventional inductors cannot be filled with circuits. This is shown in FIG. 1, which illustrates a top view an example of a conventional integrated circuit (IC) 100. As seen, the conventional IC 100 includes inductors 110 and circuits 120. Unfortunately, none of the circuits 120 can be placed under the inductors 110. This is mainly due to isolation and RF coupling issues. This leads to larger die sizes and lower dies per wafer (DPW).

Placement of metal plate can improve isolation. Unfortunately, this can also lead to a reduction in Q value due to electromagnetic energy loss. For example, Q can drop from 19 to 8, which is lower than on-chip solution. On the other hand, patterned ground plane (PGP) can improve Q (e.g., from 12 on-chip to 17). Unfortunately, this does not solve the problem of isolation. Also, there remains the issue that in such conventional inductor designs, no circuit can be placed underneath the inductors. In short, in conventional designs, a tradeoff is made between having high Q and good isolation.

In accordance with the various aspects disclosed herein, to address issues associated with conventional ICs, it is proposed to provide a structure in which a tradeoff is not necessary. In other words, the proposed structure can improve Q values and also improve isolation at the same time. This may be accomplished by providing airgaps, e.g., underneath redistribution layers (RDL) that make up the inductors. This can improve Q values. For example, the Q value may improve from 12 (with on-chip inductor) to roughly 19-21 for a same inductance e.g., @ 5 GHz. This can be very useful in integrated circuits, e.g., in low noise amplifier (LNA) ICs.

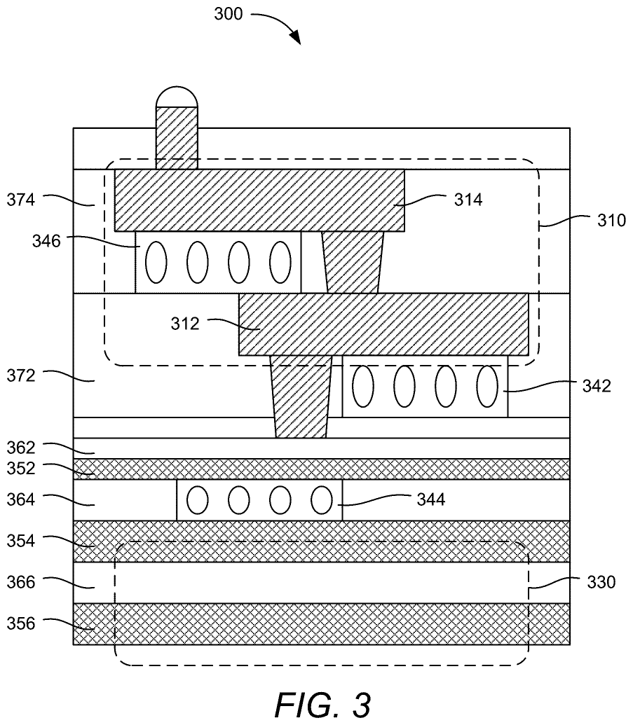

Airgaps may also be provided in the dielectric underneath the top metal layer, which can provide further decoupling effect. Providing airgaps (underneath the RDLs and/or underneath top metal layer) can reduce coupling. As a result, circuits may be placed under the inductors. This shown in FIG. 2 which illustrates a top view of an example of an integrated circuit in accordance with one or more aspects of the disclosure. The integrated circuit 200 may include one or more inductors 210, one or more circuit 220 and one or more circuits-under-inductor (CUI) 230. This can lead to smaller die and better DPW due to the improved isolation. As seen, the IC 200 can be smaller than the conventional integrated circuit 100.

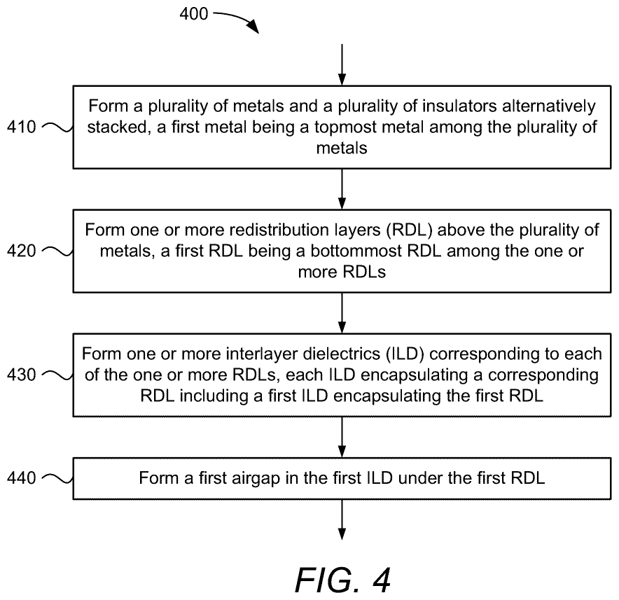

FIG. 3 illustrates an example of an integrated circuit (IC) in accordance with one or more aspects of the disclosure. FIG. 3 illustrates a side view of an exemplary IC 300. As seen, the IC 300 may include a plurality of metals and a plurality of insulators that are alternatively stacked on one another. In FIG. 3, the plurality of metals includes first metal 352, second metal 354, and third metal 356, and the plurality of insulators comprise first insulator 362, second insulator 364, and third insulator 366. It should be noted that this is merely an example, and the numbers of metals and insulators are not limited to what is shown in FIG. 3. The first metal 352 may be the top most metal. In an aspect, the first metal 352 may be formed from one or more metals including aluminum (Al). Other metals may also be formed from one or more metals including copper (Cu).

The IC 300 may also include one or more redistribution layers (RDL) above the plurality of metals. In FIG. 3, the one or more RDLs include first RDL 312 and second RDL 314. Again, this is merely an example, and the number of RDLs is not limited to what is shown in FIG. 3. The first RDL 312 may be the bottom most RDL among the one or more RDLs. In an aspect, the one or more RDLs 312, 314 may be formed from one or more metals including copper.

In an aspect, the one or more RDLs 312, 314 may be configured to as an inductor 310. The inductor 310 may be similar to the inductor 210 of FIG. 2. That is, the inductor 310 may comprise one or more turns.

The one or more RDLs 312, 314 may be encapsulated by corresponding one or more interlayer dielectrics (ILD) 372, 374. For example, the first ILD 372 may encapsulate the first RDL 312, and the second ILD 374 may encapsulate the second RDL 314. Some or all of the one or more ILDs 372, 374 may be low-K dielectrics.

One or more airgaps may be formed including airgap or airgaps that may be formed under the one or more RDLs that make up the inductor 310. For example, first airgap 342 may be formed in the first ILD 372 under the first RDL 312. In particular, the first airgap 342 may be formed under a portion of the first RDL 312 that make up the inductor 310. As a result of the first airgap 342, the Q value of the inductor 310 may be improved.

While higher amount of air is desired for isolation purposes, structural integrity of the structure is also desired. Thus, in an aspect, the first airgap 342 may constitute between 10 and 60% of the volume of space within the first ILD 372 below first RDL 312, in particular below the portion of the first RDL 312 that make up the inductor 310. It should be noted that the range of airgap percentages can depend on the material of the first ILD 372. For example, if the material provides reasonable structural integrity even if the airgap percentage is more than 60%, then the airgap volume can go beyond 60%.

Also as a result of the first airgap 342, isolation may be improved (e.g., to >−60 dBm). This allows a circuit-under-inductor (CUI) to be implemented. For example, the IC 300 may include a CUI 330 to be built vertically below the inductor 310. In an aspect, one or more metals other than the first metal 352 may be formed or otherwise configured as the circuit 330. For example, the circuit 330 may comprise portions of the second metal 354 and/or the third metal 356.

In an aspect, the first metal 352 may be patterned to vertically overlay the CUI 330. In this way, the inductor-circuit isolation may be further enhanced. Also, the first metal 352 may be tied to a voltage such as VDD or ground. Alternatively, the voltage of the first metal 352 may be left floating.

Alternatively, or in addition to the first airgap 342, a second airgap 344 may be formed in the second insulator 364. That is, the second airgap 344 may be formed in the insulator below the first metal 352. At least a portion of the second airgap 344 may vertically overlay the CUI 330. In this way, the inductor-circuit isolation can be improved that much more. In an aspect, the second airgap 344 may constitute between 10 and 60% of the volume of space within the second insulator 364 below the first metal 352. Again, this range may be different depending on the materials of the second insulator 364.

Note that in an aspect, the inductor 310 may be formed from multiple RDLs. For example, this can when the inductor 320 comprises multiple turns. Of course, it is also possible to include multiple RDLs even for a single turn inductor 310. When there are multiple RDLs at different levels such as first and second RDLs 312 and 314 as seen in FIG. 3, a third airgap 346 may be formed. The third airgap 346 may be formed in lieu of, or in addition to, the first airgap 342 and/or the second airgap 344. The third airgap 346 may be formed in the second ILD 374 under a portion of the second RDL 314 that make up the inductor 310. More generally, for at least one RDL (such as the second RDL 314) above the first RDL 312, an airgap (such as the third airgap 346) may be formed in the corresponding at least one ILD (such as the second ILD 374) that encapsulates the at least one RDL, which is above the first ILD 372. The third airgap 346 may constitute between 10% and 60% of volume of space within the at least one ILD (e.g., second ILD 374) under the at least one RDL (e.g., second RDL 314). Again, the material of the at least one ILD can influence the percentage range of the third airgap 346.

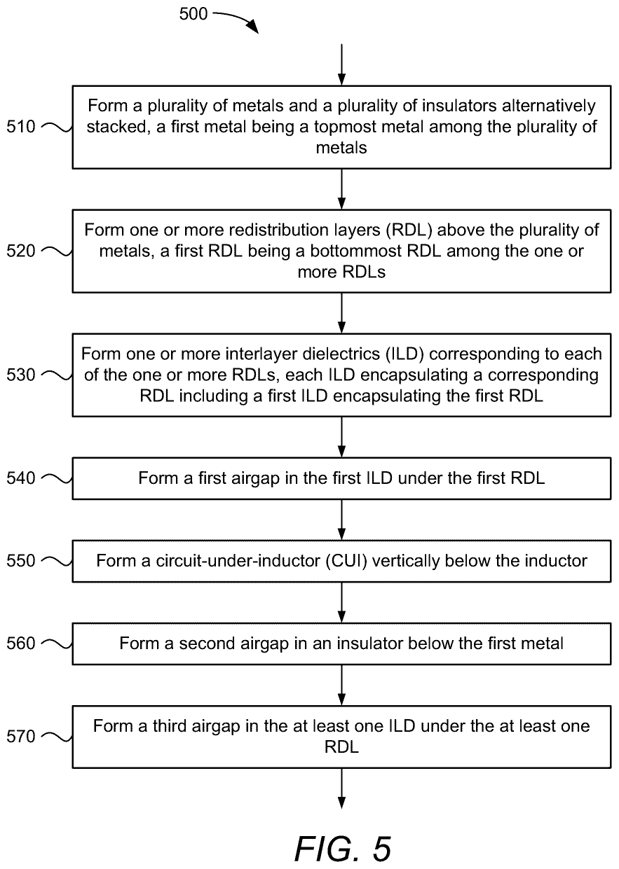

FIG. 4 illustrates a flow chart of an example method 400 of fabricating an integrated circuit, such as integrated circuits 200 and/or 300, in accordance with at one or more aspects of the disclosure.

In block 410, a plurality of metals (e.g., metals 352, 354, 356, etc.) and a plurality of insulators (e.g., insulators 362, 364, 366, etc.) may be formed to be alternatively stacked. The first metal 352 may be the top most metal among the plurality of metals.

In block 420, one or more RDLs (e.g., RDLs 312, 314, etc.) may be formed above the plurality of metals. The first RDL 312 may be the bottom most RDL among the one or more RDLs.

In block 430, one or more ILDs (e.g., ILDs 372, 374, etc.) corresponding to each of the one or more RDLs may be formed. Each ILD may encapsulate a corresponding RDL. For example, the first ILD 372 may encapsulate the first RDL 312, the second ILD 374 may encapsulate the second RDL 314, etc.

In block 440, a first airgap 342 may be formed in the first ILD 372 under the first RDL 312. Again, note that the one or more RDLs (e.g., RDLs 312, 314, etc.) may be configured as an inductor (e.g. inductor 310).

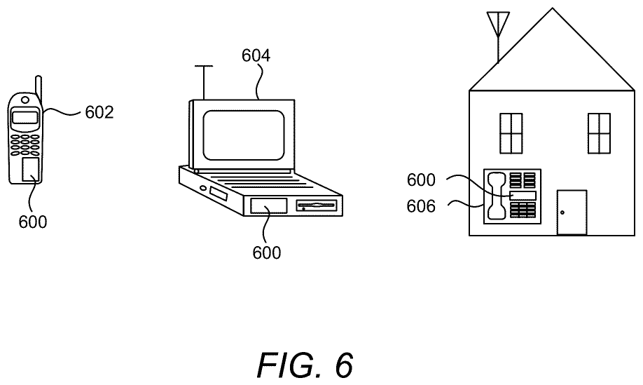

FIG. 5 illustrates a flow chart of an example method 500 of fabricating an integrated circuit, such as integrated circuit 200 and/or 300, in accordance with at one or more aspects of the disclosure. FIG. 6 may be view as being more comprehensive than FIG. 5.

Block 510 may be similar to block 410. That is, in block 510, a plurality of metals (e.g., metals 352, 354, 356, etc.) and a plurality of insulators (e.g., insulators 362, 364, 366, etc.) may be formed to be alternatively stacked. The first metal 352 may be the top most metal among the plurality of metals.

Block 520 may be similar to block 420. That is, in block 520, one or more RDLs (e.g., RDLs 312, 314, etc.) may be formed above the plurality of metals. The first RDL 312 may be the bottom most RDL among the one or more RDLs.

Block 530 may be similar to block 430. That is, in block 530, one or more ILDs (e.g., ILDs 372, 374, etc.) corresponding to each of the one or more RDLs may be formed. Each ILD may encapsulate a corresponding RDL. For example, the first ILD 372 may encapsulate the first RDL 312, the second ILD 374 may encapsulate the second RDL 314, etc.

Block 540 may be similar to block 440. That is, in block 540, a first airgap 342 may be formed in the first ILD 372 under the first RDL 312. Again, note that the one or more RDLs (e.g., RDLs 312, 314, etc.) may be configured as an inductor (e.g. inductor 310).

In block 550, the circuit-under-inductor (CUI) 330 may be formed vertically below the inductor 310.

In block 560, the second airgap 344 may be formed in the insulator 364 below the first metal 352.

In block 570, a third airgap 346 may be formed in the at least one ILD 374 under the at least one RDL 314.

FIG. 6 illustrates various electronic devices 600 that may be integrated with any of the aforementioned integrated circuits in accordance with various aspects of the disclosure. For example, a mobile phone device 602, a laptop computer device 604, and a fixed location terminal device 606 may each be considered generally user equipment (UE) and may include one or more integrated circuits (e.g., formed by methods 400 and/or 500) as described herein. The devices 602, 604, 606 illustrated in FIG. 6 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: An integrated circuit (IC), comprising: a plurality of metals and a plurality of insulators alternatively stacked, a first metal being a top most metal among the plurality of metals; one or more redistribution layers (RDL) above the plurality of metals, a first RDL being a bottom most RDL among the one or more RDLs; one or more interlayer dielectrics (ILD) corresponding to each of the one or more RDLs, each ILD encapsulating a corresponding RDL including a first ILD encapsulating the first RDL; and a first airgap formed in the first ILD under the first RDL, wherein the one or more RDLs are configured as an inductor.

Clause 2: The IC of clause 1, further comprising: a circuit-under-inductor (CUI) vertically below the inductor.

Clause 3: The IC of clause 2, wherein one or more metals of the plurality of metals other than the first metal are configured as the CUI.

Clause 4: The IC of any of clauses 2-3, wherein the first metal is patterned to vertically overlay the CUI.

Clause 5: The IC of any of clauses 2-4, wherein the first metal is configured to float in voltage.

Clause 6: The IC of any of clauses 1-5, wherein the first airgap constitutes between 10% and 60% of volume of space within the first ILD below the RDL.

Clause 7: The IC of any of clauses 1-6, further comprising: a second airgap formed in an insulator below the first metal.

Clause 8: The IC of clause 7, wherein the second airgap constitutes between 10% and 60% of volume of space within the insulator below the first metal.

Clause 9: The IC of any of clauses 1-8, wherein the one or more RDLs comprise at least one RDL above the first RDL encapsulated by corresponding at least one ILD above the first ILD, and wherein the IC further comprises a third airgap formed in the at least one ILD under the at least one RDL.

Clause 10: The IC of clause 9, wherein the third airgap constitutes between 10% and 60% of volume of space within the at least one ILD under the at least one RDL.

Clause 11: The IC of any of clauses 1-10, wherein the one or more RDLs are formed from copper (Cu).

Clause 12: The IC any of clauses 1-11, wherein the first metal is formed from aluminum (Al).

Clause 13: The IC any of clauses 1-12, wherein one or more metals of the plurality of metals other than the first metal are formed from copper (Cu).

Clause 14: The IC any of clauses 1-13, wherein the IC is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 15: A method of fabricating an integrated circuit, the method comprising: forming a plurality of metals and a plurality of insulators alternatively stacked, a first metal being a top most metal among the plurality of metals; forming one or more redistribution layers (RDL) above the plurality of metals, a first RDL being a bottom most RDL among the one or more RDLs; forming one or more interlayer dielectrics (ILD) corresponding to each of the one or more RDLs, each ILD encapsulating a corresponding RDL including a first ILD encapsulating the first RDL; and forming a first airgap in the first ILD under the first RDL, wherein the one or more RDLs are configured as an inductor.

Clause 16: The method of clause 15, further comprising: forming a circuit-under-inductor (CUI) vertically below the inductor.

Clause 17: The method of clause 16, wherein one or more metals of the plurality of metals other than the first metal are configured as the CUI.

Clause 18: The method of any of clauses 16-17, wherein the first metal is patterned to vertically overlay the CUI.

Clause 19: The method of any of clauses 16-18, wherein the first metal is configured to float in voltage.

Clause 20: The method of any of clauses 15-19, wherein the first airgap constitutes between 10% and 60% of volume of space within the first ILD below the RDL.

Clause 21: The method of any of clauses 15-20, further comprising: forming a second airgap in an insulator below the first metal.

Clause 22: The method of clause 21, wherein the second airgap constitutes between 10% and 60% of volume of space within the insulator below the first metal.

Clause 23: The method of any of clauses 15-22, wherein the one or more RDLs comprise at least one RDL above the first RDL encapsulated by corresponding at least one ILD above the first ILD, and wherein the method further comprises forming a third airgap in the at least one ILD under the at least one RDL.

Clause 24: The method of clause 23, wherein the third airgap constitutes between 10% and 60% of volume of space within the at least one ILD under the at least one RDL.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first.” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. An integrated circuit (IC), comprising:
a plurality of metals and a plurality of insulators alternatively stacked, a first metal being a top most metal among the plurality of metals;
one or more redistribution layers (RDL) above the plurality of metals, a first RDL being a bottom most RDL among the one or more RDLs;
one or more interlayer dielectrics (ILD) corresponding to each of the one or more RDLs, each ILD encapsulating a corresponding RDL including a first ILD encapsulating the first RDL; and
a first airgap formed in the first ILD under the first RDL,
wherein the one or more RDLs are configured as an inductor.

2. The IC of claim 1, further comprising:
a circuit-under-inductor (CUI) vertically below the inductor.

3. The IC of claim 2, wherein one or more metals of the plurality of metals other than the first metal are configured as the CUI.

4. The IC of claim 2, wherein the first metal is patterned to vertically overlay the CUI.

5. The IC of claim 2, wherein the first metal is configured to float in voltage.

6. The IC of claim 1, wherein the first airgap constitutes between 10% and 60% of volume of space within the first ILD below the RDL.

7. The IC of claim 1, further comprising:
a second airgap formed in an insulator below the first metal.

8. The IC of claim 7, wherein the second airgap constitutes between 10% and 60% of volume of space within the insulator below the first metal.

9. The IC of claim 1,
wherein the one or more RDLs comprise at least one RDL above the first RDL encapsulated by corresponding at least one ILD above the first ILD, and
wherein the IC further comprises a third airgap formed in the at least one ILD under the at least one RDL.

10. The IC of claim 9, wherein the third airgap constitutes between 10% and 60% of volume of space within the at least one ILD under the at least one RDL.

11. The IC of claim 1, wherein the one or more RDLs are formed from copper (Cu).

12. The IC of claim 1, wherein the first metal is formed from aluminum (Al).

13. The IC of claim 1, wherein one or more metals of the plurality of metals other than the first metal are formed from copper (Cu).

14. The IC of claim 1, wherein the IC is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

15. A method of fabricating an integrated circuit, the method comprising:
forming a plurality of metals and a plurality of insulators alternatively stacked, a first metal being a top most metal among the plurality of metals;
forming one or more redistribution layers (RDL) above the plurality of metals, a first RDL being a bottom most RDL among the one or more RDLs;
forming one or more interlayer dielectrics (ILD) corresponding to each of the one or more RDLs, each ILD encapsulating a corresponding RDL including a first ILD encapsulating the first RDL; and
forming a first airgap in the first ILD under the first RDL,
wherein the one or more RDLs are configured as an inductor.

16. The method of claim 15, further comprising:
forming a circuit-under-inductor (CUI) vertically below the inductor.

17. The method of claim 16, wherein one or more metals of the plurality of metals other than the first metal are configured as the CUI.

18. The method of claim 16, wherein the first metal is patterned to vertically overlay the CUI.

19. The method of claim 16, wherein the first metal is configured to float in voltage.

20. The method of claim 15, wherein the first airgap constitutes between 10% and 60% of volume of space within the first ILD below the RDL.

21. The method of claim 15, further comprising:
forming a second airgap in an insulator below the first metal.

22. The method of claim 21, wherein the second airgap constitutes between 10% and 60% of volume of space within the insulator below the first metal.

23. The method of claim 15,
wherein the one or more RDLs comprise at least one RDL above the first RDL encapsulated by corresponding at least one ILD above the first ILD, and
wherein the method further comprises forming a third airgap in the at least one ILD under the at least one RDL.

24. The method of claim 23, wherein the third airgap constitutes between 10% and 60% of volume of space within the at least one ILD under the at least one RDL.
